(19) United States
(12) Patent Application Publication
(10) Pub. No.: US 2026/0052870 A1
(43) Pub. Date: Feb. 19, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-Si (KR)

(72) Inventors: Ki Hyun KIM, Yongin-si (KR); Sung Hwan YOUN, Yongin-si (KR); Jun Young HEO, Yongin-si (KR)

(21) Appl. No.: 19/069,219

(22) Filed: Mar. 4, 2025

(30) Foreign Application Priority Data
Aug. 16, 2024 (KR) 10-2024-0109605

(51) Int. Cl. H10K 59/131; H10D 86/01; H10D 86/40; H10D 86/60; H10K 59/12

(52) U.S. Cl. CPC H10K 59/1315; H10D 86/0221; H10D 86/423; H10D 86/443; H10D 86/60; H10K 59/1201

(57) ABSTRACT

A display device includes a base substrate, an active layer including indium-tin-gallium-zinc oxide (ITGZO) on the base substrate and including a channel region and a contact region that is partially crystallized and formed at opposite edges of the channel region, a gate electrode on the base substrate to overlap the channel region of the active layer, a gate insulation layer between the active layer and the gate electrode, a connection electrode connected to the contact region, and a light-emitting device electrically connected to the connection electrode.

### CROSS-REFERENCE TO RELATED APPLICATION AND CLAIM OF PRIORITY

This application claims priority to Korean Patent Application No. 10-2024-0109605 filed on Aug. 16, 2024 in the Korean Intellectual Property Office (KIPO), the entire disclosure of which is incorporated by reference herein.

### TECHNICAL FIELD

The disclosure of this patent application relates to a display device, a method of manufacturing the same and an electronic device including the same. More particularly, the disclosure of this patent application relates to a display device including an oxide semiconductor layer, a method of manufacturing the same and an electronic device including the same.

### BACKGROUND

In a display device such as an organic light emitting diode (OLED) display device and a liquid display device (LCD), a display substrate including a thin film transistor (TFT) and various types of wiring is provided, and a display structure including electrodes and a light emitting layer may be formed on the display substrate.

Recently, various constructions of elements and structures of the TFT have been researched in order to stably implement a high-resolution display device. For example, an oxide semiconductor may be used as a material for an active layer included in the TFT to reduce a leakage current and improve reliability of transistor operation.

### SUMMARY

According to an aspect of the present disclosure, there is provided a display device having improved electrical property and structural reliability.

According to an aspect of the present disclosure, there is provided a method of manufacturing a display device with electrical property and structural reliability.

According to an aspect of the present disclosure, there is provided an electronic device including a display device having improved electrical property and structural reliability.

A display device may include a base substrate, an active layer including indium-tin-gallium-zinc oxide (ITGZO) on the base substrate and comprising a channel region and a contact region that is partially crystallized and formed at opposite edges channel region, a gate electrode on the base substrate to overlap the channel region of the active layer, a gate insulation layer between the active layer and the gate electrode, a connection electrode connected to the contact region, and a light-emitting device electrically connected to the connection electrode.

In some embodiments, the contact region of the active layer may include an amorphous portion and a crystallization portion that is formed on the amorphous portion to be adjacent to the connection electrode.

In some embodiments, the crystallization portion may have a mixed crystal structure including different crystal structures.

In some embodiments, the crystallization portion may include indium oxide and zinc-gallium oxide.

In some embodiments, the crystallization portion may overlap an entire width of a bottom surface of the connection electrode.

In some embodiments, an edge of the bottom surface of the connection electrode may be separated from an outermost perimeter of a top surface of the crystallization portion by a predetermined distance in a horizontal direction.

In some embodiments, the bottom surface of the connection electrode may have a shape inserted into the crystallization portion, and a boundary between the connection electrode and a top surface of the crystallization portion may be separated from an outermost perimeter of the top surface of the crystallization portion by a predetermined distance in a horizontal direction.

In some embodiments, the crystallization portion may include a plurality of thickness increasing sections and a plurality of transition sections in which a thickness of the crystallization portion increases or decreases along a horizontal direction.

In some embodiments, the crystallization portion may have a maximum thickness in a region corresponding to a point between one edge of the bottom surface of the connection electrode and a center of the bottom surface of the connection electrode.

In some embodiments, a thickness of the crystallization portion in a region corresponding to the one edge of the bottom surface of the connection electrode may be greater than a thickness of the crystallization portion in a region corresponding to the center of the bottom surface of the connection electrode.

In some embodiments, the connection electrode may include a first metal layer including titanium (Ti) adjacent to the crystallization portion in the contact region.

In some embodiments, the display device may further include an intermediate layer between the crystallization portion and the first metal layer. The intermediate layer may include an oxide containing tin (Sn) and Ti.

A display device may include a base substrate, an active layer including indium-tin-gallium-zinc oxide (ITGZO) on the base substrate and including a channel region and a contact region formed at opposite edges of the channel region, a gate electrode on the base substrate to overlap the channel region of the active layer, a gate insulation layer between the active layer and the gate electrode, a connection electrode connected to the contact region, an intermediate layer between the connection electrode and the contact region, the intermediate layer including an oxide containing tin (Sn) and Ti, and a light-emitting device electrically connected to the connection electrode.

In some embodiments, the contact region of the active layer may include an amorphous portion and a crystallization portion, and the intermediate layer may be formed between a bottom surface of the connection electrode and the crystallization portion.

In some embodiments, the crystallization portion may have a mixed crystal structure of a cubic crystal structure and a spinel crystal structure.

In some embodiments, the connection electrode may include a first metal layer including titanium (Ti), a second metal layer including aluminum (Al) and a third metal layer including titanium (Ti) which are sequentially stacked from the crystallization portion.

In a method of manufacturing a display device, an active layer including indium-tin-gallium-zinc oxide (ITGZO) may be formed on a base substrate. A gate insulation layer covering the active layer may be formed. A gate electrode may be formed on the gate insulation layer. A contact region may be formed by increasing a conductivity of opposite edges of the active layer. A connection electrode connected to the contact region may be formed. A planarization layer covering the active layer, the gate insulation layer, the gate electrode and the connection electrode may be formed. A via hole may be formed by partially removing the planarization layer to expose a top surface of the connection electrode. A pixel electrode filling the via hole and being connected to the connection electrode may be formed. The contact region of the active layer may be partially crystallized after forming the via hole or after forming the pixel electrode.

In some embodiments, the partial crystallization may be performed at a temperature of 300° C. or less.

In some embodiments, in the partial crystallization, a crystallization portion may be formed at an upper portion of the contact region and an intermediate layer containing tin (Sn) may be formed between the crystallization portion and a bottom surface of the connection electrode.

In some embodiments, a pixel defining layer covering a peripheral portion of the pixel electrode may be formed on the planarization layer. The partial crystallization may be performed after forming the pixel defining layer.

An electronic device may include a display device, a memory, and a processor configured to execute data included in the memory to control an operation of the display device. The display device may include a base substrate, an active layer including indium-tin-gallium-zinc oxide (ITGZO) on the base substrate and including a channel region and a contact region that is partially crystallized and formed at opposite edges of the channel region, a gate electrode on the base substrate to overlap the channel region of the active layer, a gate insulation layer between the active layer and the gate electrode, a connection electrode connected to the contact region, and a light-emitting device electrically connected to the connection electrode.

In some embodiments, the electronic device may include virtual or augmented reality glasses, a smartphone, a tablet PC, a laptop, a TV, a desk monitor, smart glasses, a head mounted display, a smart watches, or a vehicle display.

In a display device according to embodiments of the present invention, an active layer including a oxide semiconductor included in a transistor may include a crystallization portion. The crystallization portion may at least partially surround a connection electrode to reduce the contact resistance between the active layer and the connection electrode.

In some embodiments, an intermediate layer in which tin (Sn) is diffused may be formed between the crystallization portion and the connection electrode. An increase in the contact resistance may be suppressed by Sn included in the intermediate layer, and contact reliability between the connection electrode and the active layer may be improved.

### BRIEF DESCRIPTION OF THE DRAWINGS

FIGS. 1 and 2 are a schematic exploded perspective view and a plan view, respectively, of a display device according to example embodiments.

FIG. 3 is a pixel equivalent circuit diagram of a display device according to example embodiments.

FIG. 4 is a schematic cross-sectional view illustrating a display device according to example embodiments.

FIG. 5 is a schematic diagram of a contact stack structure of a display device according to example embodiments.

FIG. 6 to FIG. 9 are partially enlarged cross-sectional views schematically illustrating contact stack structures of a display device according to example embodiments.

FIG. 10 is a graph showing a profile of a crystallization portion in an active layer according to an embodiment.

FIGS. 11 to 20 are schematic cross-sectional views for describing a method of manufacturing a display device according to example embodiments.

FIG. 21 is a block diagram of an electronic device in accordance with an embodiment.

FIG. 22 is a schematic diagram of electronic devices in accordance with various embodiments.

### DETAILED DESCRIPTION OF THE EMBODIMENTS

Hereinafter, embodiments of the present inventive concept will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the present invention.

The terms “on”, “connected”, “coupled,” etc., used herein refers to a direct placement/connection/combination, and also refers to a case where another element is interposed between two different elements.

The terms such as “first”, “second”, “below”, “below”, “above,” “above,” etc., are used in a relative sense to distinguish different elements or positions, and do not specify an absolute position or an absolute order.

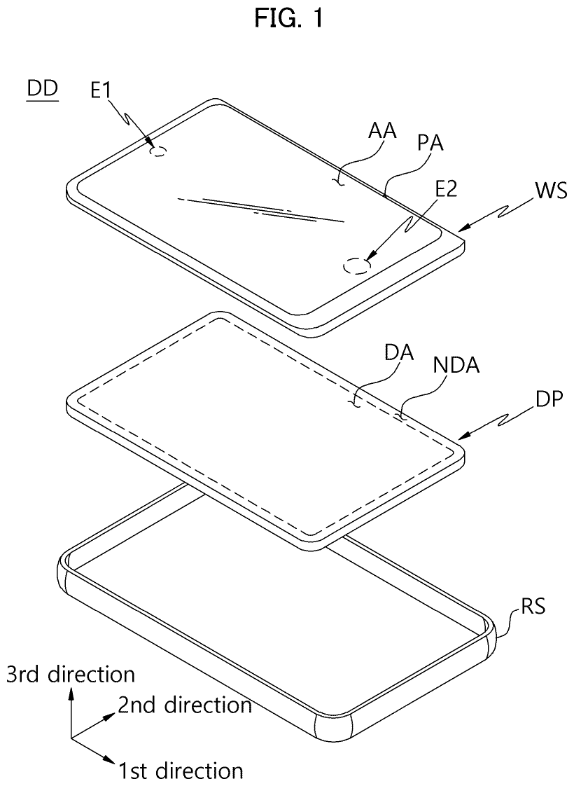

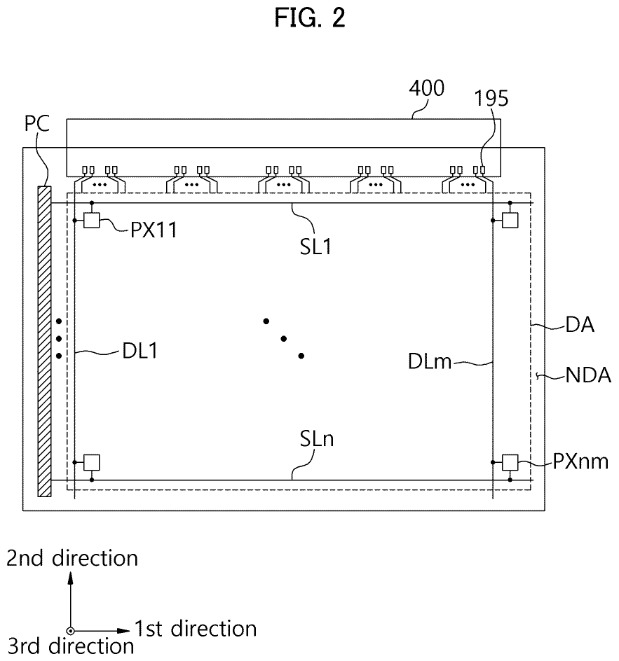

FIGS. 1 and 2 are a schematic exploded perspective view and a plan view, respectively, of a display device according to example embodiments.

In FIGS. 1 and 2, a first direction and a second direction may refer to two directions that are parallel to a display surface of a window structure WS and/or a display panel DP and perpendicular to each other. For example, the first direction may correspond to an X direction (a row direction) of a display device DD or a display panel DP, and the second direction may correspond to a Y direction (a column direction) of the display device DD or the display panel DP.

The third direction may be perpendicular to the first direction and the second direction. The third direction may correspond to a Z direction (a thickness direction) of the display device DD or the display panel DP.

Referring to FIG. 1, the display device DD may include a window structure WS, a display panel DP, and a rear structure RS. The rear structure RS, the display panel DP, and the window structure WS may be stacked along the third direction.

The display device DD may include a liquid crystal display (LCD) device, an organic light emitting diode (OLED) display device, a quantum dot light emitting diode (QLED) display device, etc. In example embodiments, the display device DD may be an OLED display device including an organic light-emitting layer. For example, the display device DD may be implemented in the form of an electronic device such as a mobile phone (smart phone), a tablet, a PC, etc.

The window structure WS may provide an external display surface recognized by a user, such as a viewing surface of a mobile phone, and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In some embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The rear structure RS may serve as a frame structure or a housing of the display device or the electronic device. A cover panel may be disposed between the rear structure RS and the display panel DP. The rear structure RS or the cover panel may include a plate (e.g., a SUS plate) that may support the display panel DP, a printed circuit board 400 (see FIG. 2), and the like. The rear structure RS or the cover panel may include an elastic material for absorbing shock of the display device DD.

Referring to FIG. 2, a plurality of pixels PX11 to PXnm may be arranged in the display area DA of the display panel DP.

In example embodiments, a pixel circuit including scan lines (or gate lines) SL1 to SLn forming first to n^{th} rows and data lines DL1 to DLm forming first to m^{th} columns may be arranged on a base substrate 100 of the display device DD or the display panel DP. Each of the pixels PX11 to PXnm may be connected to a corresponding n^{th} row scan line among a plurality of scan lines SL1 to SLn and a corresponding m^{th} column data line among a plurality of data lines DL1 to DLm.

Each of the pixels PX11 to PXnm may further include a pixel driving circuit including a transistor and a light-emitting device as will be described below. Although not illustrated in detail in FIG. 2, the pixel circuit may further include wirings such as a power line, a ground line, etc.

FIG. 2 illustrates that the data lines DL1 to DLm extend in the second direction and the scan lines SL1 to SLn extend in the first direction, but the construction of the data lines and the scan lines is not limited to that illustrated in FIG. 2.

A peripheral circuit PC may be disposed in the peripheral area PA of the display device DD or the non-display area NDA of the display panel DP. For example, the peripheral circuit PC may include a gate driving circuit. The gate driving circuit may be integrated into the display panel DP by an oxide silicon gate driver circuit (OSG) or an amorphous silicon gate driver circuit (ASG) process.

The display device DD may further include the printed circuit board 400. Pads 195 of the pixel circuit may be assembled at one end portion of the non-display area NDA. The printed circuit board 400 may be electrically connected to the pixel circuit through the pads 195. For example, the printed circuit board 400 may be electrically connected to the pads 195 by a heat-compression process using a conductive intermediate structure such as an anisotropic conductive film (ACF).

An integrated circuit (IC) such as a data driving circuit may be disposed on the printed circuit board 400. In some embodiments, an IC chip in the form of a chip-on-film (COF) may be mounted on the printed circuit board 400.

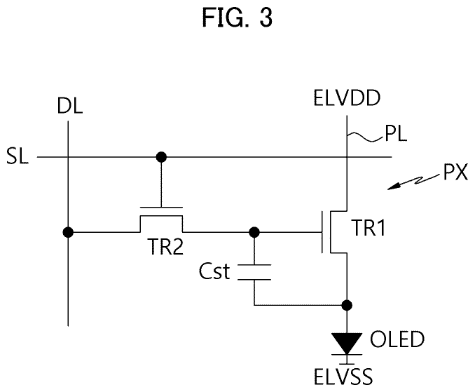

FIG. 3 is a pixel equivalent circuit diagram of a display device according to example embodiments.

Referring to FIG. 3, each pixel PX may include a first transistor TR1 and a second transistor TR2, and may further include a storage capacitor Cst. The first transistor TR1 and the second transistor TR2 may correspond to a pixel driving transistor and a switching transistor, respectively, and may have a thin film transistor (TFT) structure.

The second transistor TR2 may be connected to a scan line SL and a data line DL. The second transistor TR2 may be turned on by a gate pulse supplied from the scan line SL to transmit a data signal supplied from the data line DL to the first transistor TR1.

The storage capacitor Cst may be connected to the second transistor TR2 and a power line PL. The storage capacitor Cst may store a voltage corresponding to a difference between a voltage transferred from the second transistor TR2 and a driving voltage ELVDD supplied from the power line PL.

The first transistor TR1 may be connected to the power line PL and the storage capacitor Cst, and may control a driving current flowing through an organic light emitting diode OLED in response to a voltage stored in the storage capacitor Cst. Accordingly, a luminance of light emitted from the organic light emitting diode OLED may be adjusted. The pixel PX may emit red, green, blue or white light.

A common voltage ELVSS may be supplied to an opposite electrode (e.g., a cathode) of the organic light emitting diode OLED.

At least one transistor of the first transistor TR1 and the second transistor TR2 may include an oxide semiconductor as an active layer, and may have a contact stack structure CSS (see FIGS. 5 to 9) to be described below.

In FIG. 3, a structure including two thin film transistors and one storage capacitor Cst (a 2T1C structure) for each pixel PX is illustrated, but the pixel structure of the display device disclosed in this application is not limited thereto.

For example, each pixel PX may include three or more transistors, and may have a structure including 5 transistors and 1 capacitor (5T1C), 7 transistors and 1 capacitor (7T1C), 7 transistors and two capacitors (7T2C), or the like. At least one of transistors included in each pixel PX may include an oxide semiconductor as an active layer, and may have the contact stack structure CSS (see FIGS. 5 to 9) to be described below.

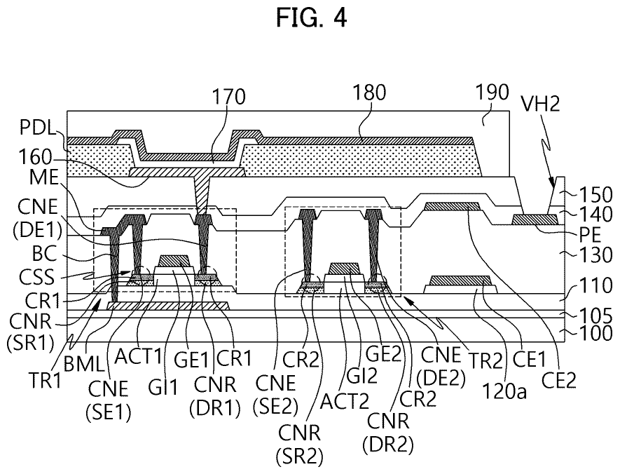

FIG. 4 is a schematic cross-sectional view illustrating a display device according to example embodiments. For example, FIG. 4 includes an example arrangement and stack structure of elements included in the pixel illustrated in FIG. 3.

Referring to FIG. 4, the display device may include transistors TR1 and TR2 formed on a base substrate 100 and a light-emitting device electrically interacting with the transistor.

The base substrate 100 may be provided as a back-plane substrate of a display device. A glass substrate or a plastic substrate may be used as the base substrate 100. In some embodiments, the base substrate 100 may include a polymer material having transparency and flexibility. In this case, the base substrate 100 may be used in a transparent flexible display device.

For example, the base substrate 100 may include a polymer material such as polyimide, polysiloxane, an epoxy resin, an acrylic resin, polyester, or the like. In an embodiment, the base substrate 100 may include polyimide.

A barrier layer 105 may be formed on a top surface of the base substrate 100. Moisture penetrating through the base substrate 100 may be blocked by the barrier layer 105, and diffusion of impurities between the base substrate 100 and structures formed on the base substrate 100 may be blocked. The barrier layer 105 may be formed over the display area DA and the non-display area NDA of the base substrate 100, and may entirely cover the top surface of the base substrate 100.

The barrier layer 105 may include, e.g., an inorganic insulating material such as silicon oxide, silicon nitride or silicon oxynitride. These may be used alone or in a combination of two or more therefrom. In some embodiments, the barrier layer 105 may have a stacked structure including a silicon oxide layer and a silicon nitride layer. In some embodiments, the barrier layer 105 may include an organic layer, and may have a multi-layered structure of the organic layer and the inorganic layer.

A back metal layer BML may be disposed on the barrier layer 105. The back metal layer BML may overlap a first active layer ACT1 in the third direction under the first transistor TR1. The back metal layer BML may serve as a blocking layer of an external light with respect to a pixel driving transistor. The back metal layer BML may serve as a bias electrode. In an embodiment, the back metal layer BML may have an island-shaped floating electrode separated from another wiring or electrode.

The back metal layer BML may include a metal such as silver (Ag), molybdenum (Mo), aluminum (Al), tungsten (W), copper (Cu), titanium (Ti), or the like, or an alloy including at least one therefrom.

A buffer layer 110 may be formed on the base substrate 100 to cover the back metal layer BML. The buffer layer 110 may be formed entirely on the display area DA and the non-display area NDA. In some embodiments, the buffer layer 110 may be formed on an entire top surface of the barrier layer 105 to cover the back metal layer BML.

The buffer layer 110 may block or prevent impurities from the base substrate 100 from penetrating into active layers ACT1 and ACT2. Further, the buffer layer 110 may serve as a dielectric layer separating the back metal layer BML and the active layers ACT1 and ACT2 from each other.

The buffer layer 110 may include an inorganic insulating material such as silicon oxide, silicon nitride, silicon oxynitride, aluminum oxide, titanium oxide, tantalum oxide, hafnium oxide, or the like.

A transistor may be disposed on the buffer layer 110. The transistor may include a first transistor TR1 and a second transistor TR2.

The first transistor TR1 may include a first active layer ACT1, a first gate insulation layer GI1 and a first gate electrode GE1. The second transistor TR2 may include a second active layer ACT2, a second gate insulation layer GI2 and a second gate electrode GE2. As described above, in some embodiments, the first transistor TR1 and the second transistor TR2 may serve as a pixel driving transistor and a switching transistor, respectively.

The first active layer ACT1 and the second active layer ACT2 may be disposed on the buffer layer 110. In an embodiment, the first active layer ACT1 and the second active layer ACT2 may be directly formed on a top surface of the buffer layer 110.

At least one of the first active layer ACT1 and the second active layer ACT2 may include an oxide semiconductor. In example embodiments, both the first active layer ACT1 and the second active layer ACT2 may include an oxide semiconductor.

In an embodiment, any one of the first active layer ACT1 and the second active layer ACT2 may include the oxide semiconductor, and the other one may include a silicon-based semiconductor (e.g., polysilicon or amorphous silicon).

Hereinafter, elements/structure of the transistor and the display device will be described based on an embodiment in which both the first active layer ACT1 and the second active layer ACT2 include the oxide semiconductor.

The active layers ACT1 and ACT2 may include a quaternary metal oxide semiconductor having a relatively high mobility. According to embodiments of the present invention, the active layers ACT1 and ACT2 may include indium-tin-gallium-zinc oxide (ITGZO).

In an embodiment, one of the first active layer ACT1 and the second active layer ACT2 may include ITGZO having a high mobility, and the other one may include an oxide semiconductor having a relatively low mobility (e.g., a ternary metal oxide semiconductor such as indium-gallium-zinc oxide (IGZO), indium-tin-gallium-oxide (ITGO) or indium-tin-zinc oxide (ITZO)). For example, the first active layer ACT1 may include ITGZO, and the second active layer ACT2 may include the ternary metal oxide semiconductor. Alternatively, the first active layer ACT1 may include the ternary metal oxide semiconductor, and the second active layer ACT2 may include ITGZO.

Hereinafter, elements/structure of the transistor and the display device will be described based on an embodiment in which both the first active layer ACT1 and the second active layer ACT2 include ITGZO.

The active layers ACT1 and ACT2 may include a channel region and a contact region CNR. The contact region CNR may include a source region and a drain region. The contact region CNR may have a higher conductivity than that of the channel region.

For example, the contact region CNR (a first contact region) included in the first active layer ACT1 may include a first source region SR1 and a first drain region DR1, and a region between the first source region SR1 and the first drain region DR1 may be defined as a first channel region. The contact region CNR (a second contact region) included in the second active layer ACT2 may include a second source region SR2 and a second drain region DR2, and a region between the second source region SR2 and the second drain region DR2 may be defined as a second channel region.

The first gate insulation layer GI1 and the first gate electrode GE1 may be sequentially stacked on the first active layer ACT1. The second gate insulation layer GI2 and the second gate electrode GE2 may be sequentially stacked on the second active layer ACT2. In this case, the transistors TR1 and TR2 may have a top-gate structure in which the gate electrodes GE1 and GE2 are disposed on the active layers ACT1 and ACT2.

In an embodiment, the transistors TR1 and TR2 may have a bottom-gate structure in which the gate electrodes GE1 and GE2 are disposed under the active layers ACT1 and ACT2. In this case, the gate electrodes GE1 and GE2 may be disposed on the buffer layer 110, and the gate insulation layers GI1 and GI2 may cover the gate electrodes GE1 and GE2. The active layers ACT1 and ACT2 may be disposed on the gate insulation layers GI1 and GI2 such that the channel region overlaps the gate electrodes GE1 and GE2 with the gate insulation layers GI1 and GI2 interposed therebetween.

Hereinafter, elements/structure of the transistor and the display device will be described based on an embodiment including the top-gate structure.

The first gate insulation layer GI1 may be substantially formed on the first channel region, and a portion of the first active layer ACT1 not covered by the first gate insulation layer GI1 may substantially serve as the first contact region including the first source region SR1 and the first drain region DR1.

The second gate insulation layer GI2 may be formed substantially on the second channel region, and a portion of the second active layer ACT2 not covered by the second gate insulation layer GI2 may serve as a second contact region substantially including the second source region SR2 and the second drain region DR2.

The gate insulation layers GI1 and GI2 may include an inorganic insulating material such as silicon oxide, silicon nitride, silicon oxynitride, aluminum oxide, titanium oxide, tantalum oxide, hafnium oxide, or the like.

In some embodiments, a sub-insulation layer 120a spaced apart from the gate insulation layers GI1 and GI2 may be formed on the buffer layer 110. The sub-insulation layer 120a may include substantially the same insulating material as that of the gate insulation layers GI1 and GI2.

The gate electrodes GE1 and GE2 may be disposed on a top surface of the gate insulation layers GI1 and GI2 to substantially overlap the channel regions of the active layers ACT1 and ACT2 together with the gate insulation layers GI1 and GI2.

The gate electrodes GE1 and GE2 may include a metal such as tungsten (W), molybdenum (Mo), aluminum (Al), copper (Cu), titanium (Ti), chromium (Cr), nickel (Ni), silver (Ag), or an alloy including at least one therefrom.

In some embodiments, a first sub-electrode CE1 spaced apart from the gate electrodes GE1 and GE2 may be disposed on the sub-insulation layer 120a. The first sub-electrode CE1 may include substantially the same conductive material as that of the gate electrodes GE1 and GE2.

An insulating interlayer 130 covering the transistors TR1 and TR2 and the first sub-electrode CE1 may be formed on the buffer layer 110. The insulating interlayer 130 may include an inorganic insulating material such as silicon oxide, silicon nitride, silicon oxynitride, aluminum oxide, titanium oxide, tantalum oxide, hafnium oxide, or the like. The insulating interlayer 130 may have a single-layered structure or a multi-layered structure including different materials (e.g., silicon oxide and silicon nitride).

Connection electrodes CNE penetrating the insulating interlayer 130 and being electrically connected to the contact region CNR may be formed on the insulating interlayer 130. The connection electrodes CNE may include first connection electrodes SE1 and DE1 and second connection electrodes SE2 and DE2.

The first connection electrodes SE1 and DE1 may be connected to or in contact with the first contact regions SR1 and DR1 of the first transistor TR1. The first connection electrodes SE1 and DE1 may include a first source electrode SE1 connected to or in contact with the first source region SR1 and a first drain electrode DE1 connected to or in contact with the first drain region DR1.

The second connection electrodes SE2 and DE2 may be connected to or in contact with the second contact regions SR2 and DR2 of the second transistor TR2. The second connection electrodes SE2 and DE2 may include a second source electrode SE2 connected to or in contact with the second source region SR2 and a second drain electrode DE2 connected to or in contact with the second drain region DR2.

In some embodiments, the first source electrode SE1 may include a back contact BC connected to or in contact with the back metal layer BML. The back contact BC may be connected to the first source electrode SE1 through a merging electrode ME disposed on the insulating interlayer 130.

The connection electrode CNE may include a metal layer. The metal layer may include a titanium (Ti) layer. The metal layer may have a multi-layered structure including a titanium layer. In example embodiments, the connection electrode CNE may have a multi-layered structure including a first titanium (Ti) layer/an aluminum (Al) layer/a second titanium layer (Ti). The first titanium layer may be adjacent to the contact region CNR.

According to embodiments of the present disclosure, the contact region CNR may include crystallization portions CR1 and CR2. In example embodiments, each of the first source region SR1 and the first drain region DR1 may include a first crystallization portion CR1 at an upper portion thereof. The second source region SR2 and the second drain region DR2 may each include a second crystallization portion CR2 at an upper portion thereof.

The crystallization portions CR1 and CR2 may be formed by partially crystallizing the active layers ACT1 and ACT2 formed of an amorphous ITGZO. The first titanium layer of the connection electrode CNE may be disposed on the crystallization portions CR1 and CR2 to define a contact stack structure CSS indicated by a dotted circle in FIG. 4.

Elements and construction of the contact stack structure CSS will be described in more detail with reference to FIGS. 5 to 10.

The transistors TR1 and TR2 are defined by the combination of the above-described elements and structures, and the connection electrodes SE1, DE1, SE2, and DE2 may be connected to the transistors TR1 and TR2 through the contact regions SR1, DR1, SR2, and DR2 to transmit current/voltage.

For example, the data line DL and/or the power line PL may be connected to the source electrodes SE1 and SE2, and the gate electrodes GE1 and GE2 may protrude or extend from the scan line SL.

In some embodiments, a second sub-electrode CE2 facing the first sub-electrode CE1 with the insulating interlayer 130 interposed therebetween may be disposed on the insulating interlayer 130. A storage capacitor Cst may be defined by the first and second sub-electrodes CE1 and CE2. The second sub-electrode CE2 may include substantially the same conductive material as that of the connection electrode CNE.

In some embodiments, a pad electrode PE may be disposed on the insulating interlayer 130. The pad electrode PE may include substantially the same conductive material as that of the second sub-electrode CE2 and the connection electrode CNE. The pad electrode PE may be disposed in the non-display area NDA and may serve as the pad 195 that is illustrated in FIG. 2.

A passivation layer 140 covering the connection electrodes CNE, the second sub-electrode CE2 and the pad electrode PE may be formed on the insulating interlayer 130. A planarization layer 150 may be formed on the passivation layer 140.

The passivation layer 140 may include an inorganic insulating material such as silicon oxide, silicon nitride, silicon oxynitride, aluminum oxide, titanium oxide, tantalum oxide, hafnium oxide, or the like. The planarization layer 150 may include an organic material such as polyimide, an epoxy resin, an acrylic resin, polyester, siloxane resin, benzocyclobutene (BCB), or the like.

A first via hole VH1 (see FIG. 19) that may penetrate the planarization layer 150 and the passivation layer 140 to expose at least one of the connection electrodes CNE, and a second via hole VH2 that may expose the pad electrode PE may be formed. In example embodiments, a top surface of the first drain electrode DE1 may be exposed through the first via hole VH1. In an embodiment, a top surface of the first source electrode SE1 may be exposed through the first via hole VH1.

A pixel electrode 160 filling the first via hole VH1 may be disposed on the planarization layer 150. The pixel electrode 160 may be electrically connected to the first transistor TR1 through the first drain electrode DE1. The pixel electrode 160 may be in contact with or connected to the top surface of the first drain electrode DE1. In an embodiment, the pixel electrode 160 may be in contact with or connected to the top surface of the first source electrode SE1.

The pixel electrode 160 may serve as an anode and may include a high work function conductive material to promote hole injection. The pixel electrode 160 may be provided as a transmissive electrode. The pixel electrode 160 may include a transparent conductive oxide such as indium tin oxide (ITO), indium zinc oxide (IZO), zinc oxide (ZnO) and indium tin oxide (ITZO).

The pixel electrode 160 may be provided as a transflective electrode or a reflective electrode. The pixel electrode 160 may include at least one of Ag, Mg, Cu, Al, Pt, Pd, Au, Ni, Nd, Ir, Cr, Li, Li, Ca, LiF, Mo, Ti, W, In, Sn, and Zn, or an alloy of two or more therefrom.

The pixel electrode 160 may have a single-layered structure or a multi-layered structure. For example, the pixel electrode 160 may have a triple-layered structure of ITO/Ag/ITO.

A pixel defining layer PDL may be formed on the planarization layer 150 and be removed from an area above the pixel electrode 160. The pixel defining layer PDL may cover a peripheral portion of the pixel electrode 160 while exposing a central portion of the pixel electrode 160.

An emission region may be defined by a sidewall of the pixel defining layer PDL. For example, a green emission region, a blue emission region and a red emission region may be separated and defined by the pixel defining layer PDL.

The pixel defining layer PDL may include, e.g., an organic material such as a polysiloxane resin, a polyimide resin, an acrylic resin, or the like. The pixel defining layer PDL may include a colorant material such as a black pigment/dye dispersed in a resin material.

An emission layer 170 may be disposed on the exposed surface of the pixel electrode 160. The emission layer 170 may include an organic light-emitting material that may be independently patterned for each of a red pixel, a green pixel and a blue pixel to generate lights of different colors for each pixel.

For example, the organic light-emitting material may include a host material excited by a hole and an electron, and a dopant material that may enhance a luminous efficiency through absorption and release of energy.

In an embodiment, the emission layer 170 may be a white light-emitting layer. In this case, the emission layer 170 may extend continuously and commonly throughout a plurality of pixels. In an embodiment, the emission layer 170 may include light-emitting layers corresponding to a plurality of lights of different colors, and a stack having a tandem structure may be disposed on the pixel electrode 160.

In some embodiments, a hole transport layer (HTL) and/or a hole injection layer (HIL) may be further included between the pixel electrode 160 and the emission layer 170.

A counter electrode 180 may be disposed on a top surface of the pixel defining layer PDL and the emission layer 170. The counter electrode 180 may be a common electrode that may be continuously provided commonly throughout a plurality of the emission regions or the pixels.

The counter electrode 180 may serve as an electron injection electrode or a cathode. The counter electrode 180 may include a metal, an alloy, an electrically conductive compound, or the like, having a low work function.

For example, the counter electrode 180 may include lithium (Li), silver (Ag), magnesium (Mg), aluminum (Al), aluminum-lithium (Al-Li), calcium (Ca), magnesium-indium (Mg—In), magnesium-silver (Mg—Ag), ytterbium (Yb), silver-ytterbium (Ag—Yb), ITO, IZO, or the like. These may be used alone or in combination of two or more therefrom.

The counter electrode 180 may be provided as a transmissive electrode, a transflective electrode, or a reflective electrode. The counter electrode 180 may have a single-layered structure or a multi-layered structure.

In some embodiments, an electron transport layer (ETL) and/or an electron injection layer (EIL) may be further included between the counter electrode 180 and the light emitting layer 170.

A light-emitting device may be defined by the pixel electrode 160, the emission layer 170 and the counter electrode 180. The light-emitting device may be provided as an organic light emitting diode (OLED) device.

An encapsulation layer 190 may be formed on the counter electrode 180. The encapsulation layer 190 may be disposed on the pixel defining layer PDL and the light-emitting devices to protect the light-emitting devices from moisture or oxygen.

The encapsulation layer 190 may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE) or a combination thereof; or a combination of the inorganic layer and the organic layer.

The encapsulation layer 190 may be formed as a single-layered structure or a multi-layered structure. In some embodiments, the encapsulation layer 190 may have a sequential stacked structure of a first inorganic layer, an organic layer and a second inorganic layer.

In some embodiments, a color control layer overlapping the emission layer 170 may be disposed on the encapsulation layer 190. The color control layer may include a color conversion layer including quantum dots and/or a color filter.

FIG. 5 is a schematic diagram of a contact stack structure of a display device according to example embodiments.

Referring to FIG. 5, as described with reference to FIG. 4, the connection electrode CNE may be disposed on the contact region CNR of the active layer ACT to define the contact stack structure CSS. The connection electrode CNE may include a metal layer ML. The metal layer ML may include titanium Ti.

As described above, the active layer ACT may include a partially crystallized ITGZO layer. In example embodiments, the contact region CNR may include an amorphous portion AR and a crystallization portion CR. The metal layer ML of the connection electrode CNE may be stacked on the crystallization portion CR.

The crystallization portion CR may be provided as a substantial contact region of the connection electrode CNE. A contact resistance between the connection electrode CNE and the active layer ACT may be reduced by the crystallization portion CR. Further, an adhesion between the connection electrode CNE and the active layer ACT may be increased by the crystallization portion CR.

Accordingly, a contact failure due to a lift-off of the connection electrode CNE from the active layer ACT may be prevented, and the contact resistance may be further reduced. Thus, the voltage applied to the display device may be lowered, and voltage/current drop may be suppressed.

In some embodiments, the crystallization portion CR may have a mixed crystal structure including different crystal structures. The crystallization portion CR may include indium oxide (e.g., In₂O₃) and zinc-gallium oxide (e.g., ZnGa₂O₄). Indium oxide may have a cubic crystal structure, and zinc-gallium oxide may have a spinel crystal structure.

An intermediate layer ITL may be formed between the crystallization portion CR and the metal layer ML. The intermediate layer ITL may include a first metal element derived from the metal layer ML included in the connection electrode CNE and a second metal element derived from the active layer ACT.

In some embodiments, the intermediate layer ITL may include titanium (Ti) (the first metal element) and tin (Sn) (the second metal element). In some embodiments, the intermediate layer ITL may include an oxide containing tin and titanium (SnTiOx). In an embodiment, the intermediate layer ITL may not include nitrogen (N).

The intermediate layer ITL may be disposed between the connection electrode CNE and the active layer ACT to further reduce the contact resistance, and an electrical conductivity may be enhanced between the connection electrode CNE and the active layer ACT.

Additionally, the intermediate layer ITL may be doped with tin (Sn) to reduce a band gap of a titanium oxide layer. Thus, the contact resistance may be further reduced, and the voltage that is required for operation of the transistor may be reduced.

According to the above-described embodiments, the active layer ACT may include the amorphous portion AR and the crystallization portion CR. The amorphous portion AR may dissolve defects in the active layer ACT generated when forming the crystallization portion. Thus, overall crystal defects of the active layer ACT may be reduced, and contact stability and resistance may be effectively reduced by the crystallization portion CR.

The intermediate layer ITL may also buffer or reduce defects generated in the crystallization portion CR. Accordingly, the crystallization portion CR may be disposed between the intermediate layer ITL and the amorphous portion AR, reducing resistance.

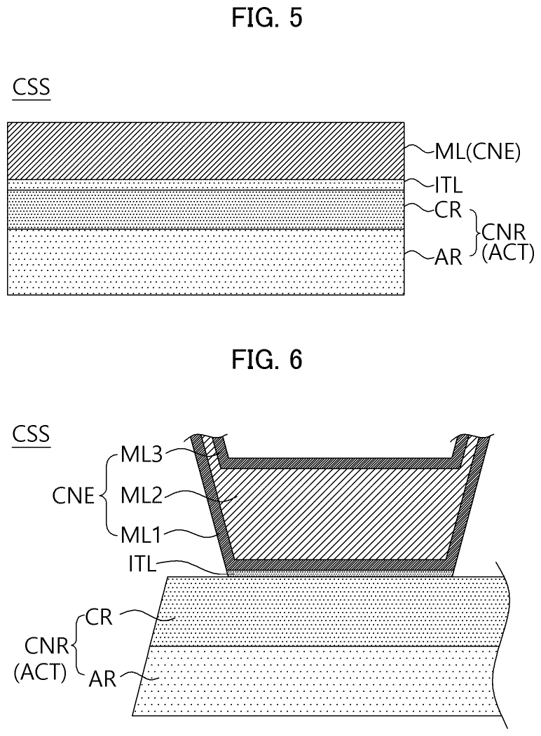

FIG. 6 to FIG. 9 are enlarged cross-sectional views schematically illustrating contact stack structures of a display device according to example embodiments.

Referring to FIG. 6, the connection electrode CNE may have a multi-layered structure including a first metal layer ML1, a second metal layer ML2 and a third metal layer ML3. In example embodiments, the first metal layer ML1, the second metal layer ML2 and the third metal layer ML3 may be a Ti layer, an Al layer and a Ti layer, respectively. The first metal layer ML1, the second metal layer ML2 and the third metal layer ML3 may be sequentially stacked from a top surface of the contact region CNR.

The contact region CNR of the active layer ACT may include the amorphous portion AR including the amorphous ITGZO. The contact region CNR may include the crystallization portion CR formed by partially crystallizing ITGZO. The intermediate layer ITL may include tin and the titanium-containing oxide (SnTiOx), and may be disposed between the first metal layer ML1 and the crystallization portion CR.

The intermediate layer ITL may be directly formed on the top surface of the crystallization portion CR. The intermediate layer ITL may partially cover the top surface of the crystallization portion CR. In example embodiments, the intermediate layer ITL may be in direct contact with the crystallization portion CR and the first metal layer ML1, and may buffer or suppress an abrupt increase in the contact resistance.

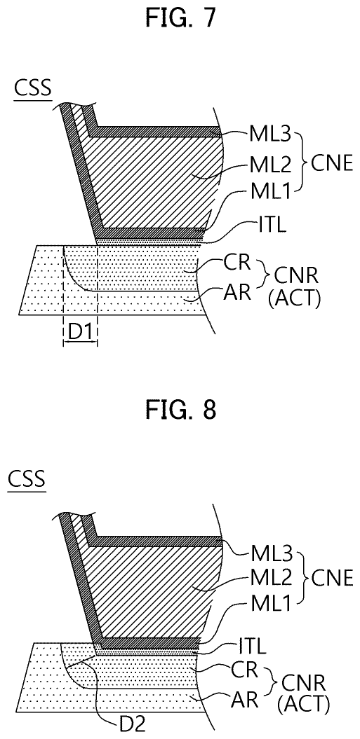

Referring to FIG. 7, the crystallization portion CR may be formed at an upper portion of the contact region CNR. In example embodiments, the crystallization portion CR may have a well (e.g., an n+ type well) shape formed in the contact region CNR. For example, a portion of a top surface of the source region or the drain region may form a top of the crystallization portion CR.

In example embodiments, in a plan view (when viewed from the third direction), a bottom surface of the connection electrode CNE may be included in the top surface of the crystallization portion CR. In this case, a bottom edge of the connection electrode CNE may be spaced apart from a circumference (an outermost perimeter) of the top surface of the crystallization portion CR by a predetermined distance (a first spacing distance D1). In some embodiments, as described above, the intermediate layer ITL may be formed between the first metal layer ML1 and the crystallization portion CR. Herein, the intermediate layer ITL may be regarded as an element included in the connection electrode CNE. In this case, the first spacing distance is defined as a distance between a bottom edge of the intermediate layer ITL and the circumference of the top surface of the crystallization portion CR.

In an embodiment, the first spacing distance D1 may be in a range from 10 nm to 30 nm, from 10 nm to 25 nm, or from 10 nm to 20 nm.

As described above, the top surface of the crystallization portion CR may entirely cover the bottom surface of the connection electrode CNE. Accordingly, contact stability of the connection electrode CNE may be further improved while effectively reducing the contact resistance. The top surface of the crystallization portion CR may also overlap an entire width of the intermediate layer ITL, the “width” being measured in the horizontal direction.

Referring to FIG. 8, the connection electrode CNE may be partially inserted into or buried in an upper portion of the contact region CNR. In this case, in the cross-section of FIG. 8, the connection electrode CNE or a bottom surface of the first metal layer ML1 may be located below a top surface of the contact region CNR.

In some embodiments, a bottom portion of the connection electrode CNE may be substantially surrounded by the crystallization portion CR of the active layer ACT. Accordingly, a contact area between the crystallization portion CR and the connection electrode CNE may be increased, the contact resistance may be further reduced, and contact stability of the connection electrode CNE may be further improved.

For example, the bottom portion of the connection electrode CNE may have a shape inserted into the crystallization portion CR. A boundary between the connection electrode CNE and the top surface of the crystallization portion CR may be separated from an outermost circumference of the top surface of the crystallization portion CR by a specific distance (e.g., a first separation distance D1 of FIG. 7).

As illustrated in FIG. 8, the shortest distance (a second separation distance D2) between a bottom edge of the connection electrode CNE and the circumference of the crystallization portion CR may be maintained in a specific range. In an embodiment, the second separation distance D2 may be in a range from 10 nm to 30 nm, from 10 nm to 25 nm, or from 10 nm to 20 nm. In some embodiments, as described above, the intermediate layer ITL may be formed between the first metal layer ML1 and the crystallization portion CR. Herein, the intermediate layer ITL may be regarded as an element included in the connection electrode CNE. In this case, the second spacing distance is defined as the shortest distance between a bottom edge of the intermediate layer ITL and the circumference of the crystallization portion CR.

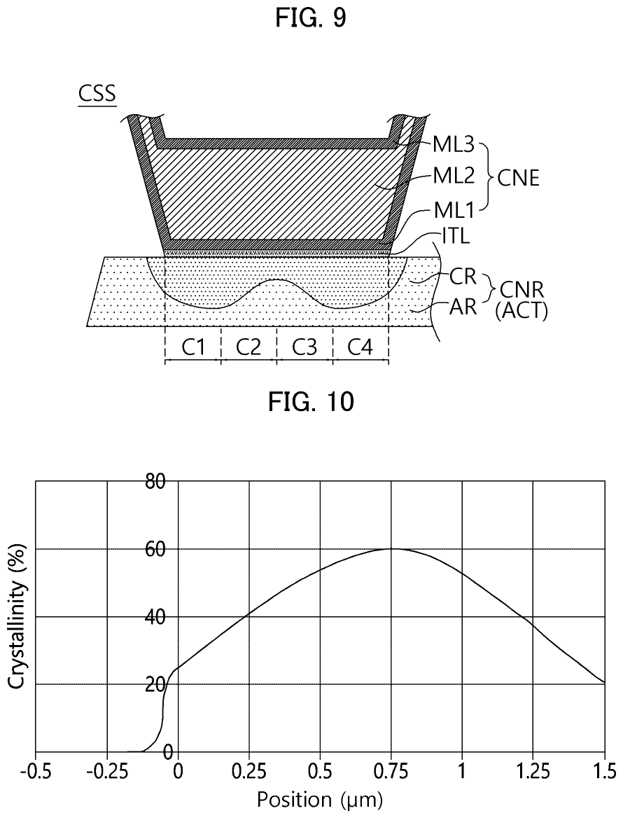

Referring to FIG. 9, a thickness of the crystallization portion CR may vary along a horizontal direction (which is the first direction, the second direction, or a specific direction parallel thereto).

In example embodiments, in the cross-section of FIG. 9, the crystallization portion CR may include a thick section, a thin section, and transition sections with increasing or decreasing thickness in a direction (horizontal direction) from one edge to the other edge of the bottom surface of the connection electrode CNE.

As shown in FIG. 9, the crystallization portion CR may include a plurality of transition sections, some of which increase thickness and others decrease thickness. The crystallization portion CR may include a first section C1, a second section C2, a third section C3, and a fourth section C4. In each of the first section C1, the second section C2, the third section C3, and the fourth section C4, the thickness of the crystallization portion CR may be increasing or decreasing.

The first section C1 may include a section in which the thickness of the crystallization part CR increases along the horizontal direction from a point of the crystallization portion CR corresponding to the one edge of the connection electrode CNE. A length of the first section C1 may be less than ½ of a width of the bottom surface of the connection electrode CNE. For example, the length of the first section C1 may be in a range from ⅕ to ⅖ of the width of the bottom surface of the connection electrode CNE.

In the second section C2, the thickness of the crystallization portion CR may decrease along the horizontal direction. In the third section C3, the thickness of the crystallization portion CR may increase along the horizontal direction.

In a section defined by the second section C2 and the third section C3, a point corresponding to a center of the bottom surface of the connection electrode CNE may be included. In an embodiment, a boundary between the second section C2 and the third section C3 may be divided at a point substantially corresponding to the center of the crystallization portion CR.

In the fourth section C4, the thickness of the crystallization portion CR may increase again. For example, a length of the fourth section C4 may be in a range from ⅕ to ⅖ of the width of the bottom surface of the connection electrode CNE.

FIG. 10 is a graph showing a profile of a crystallization portion in an active layer according to an embodiment. FIG. 10 shows an example of a thickness profile of the crystallization portion CR as described with reference to FIG. 9.

For example, FIG. 10 shows a crystallinity (a degree of crystallization) of the crystallization portion CR from a region corresponding to one edge of the bottom of the connection electrode CNE (position 0) to a region corresponding to the center of the bottom surface of the connection electrode CNE (1.5 μm) (a position corresponding to ½ of the width of the bottom surface of the connection electrode CNE (3 μm)).

In FIG. 10, the crystallinity may indicate a degree of crystallization in each region from the top surface to the bottom surface of the contact region CNR of the active layer ACT, and may indicate the thickness of the crystallization portion CR at the corresponding region.

Referring to FIG. 10, a point at which the crystallinity (the thickness of the crystallization portion CR) has a maximum value may be positioned between the one edge of the bottom surface of the connection electrode CNE and the center of the bottom surface. For example, the thickness of the crystallization portion CR may have a maximum value at a position (0.75 μm) substantially corresponding to one quarter of the width of the bottom surface of the connection electrode CNE.

In some embodiments, a crystallinity (a thickness of the crystallization portion CR) of the connection electrode CNE at a point corresponding to the one edge of the bottom surface may be greater than a crystallinity (a thickness of the crystallization portion CR) at a point corresponding to the center of the bottom surface.

As described above, the crystallinity or the thickness of the crystallization portion CR may be relatively increased at a portion adjacent to both edges of the bottom surface of the connection electrode CNE. Therefore, the contact resistance that may be increased at the edges may be suppressed or buffered, and the lift-off of the connection electrode CNE may be stably suppressed at the edges.

The crystallinity graph of FIG. 10 illustrates an example in which the bottom width of the connection electrode CNE is 3 μm. The contact stack structure CSS of the present invention is not limited to the profile of FIG. 10.

In example embodiments, the crystallinity may be measured using a four-dimensional scanning transmission electron microscope (4D-STEM) while scanning a cross-section of the contact region (CNR).

After obtaining a diffraction pattern using 4D-STEM, a variation of a diffraction intensity (V₂D) may be measured at a point where a first ring of the diffraction pattern appears. The crystallinity may be measured by calculating a ratio of a pixels having the V₂D of 0.03 or more of all pixels.

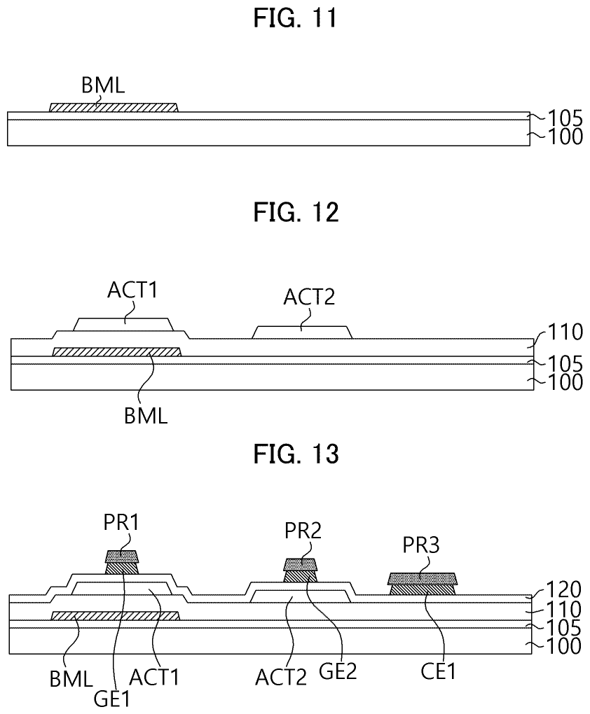

FIGS. 11 to 22 are schematic cross-sectional views illustrating a method of manufacturing a display device according to embodiments. For example, detailed descriptions of materials of elements described with reference to FIG. 4 are omitted.

Referring to FIG. 11, the barrier layer 105 may be formed on the base substrate 100. The back metal layer BML may be formed on the barrier layer 105.

The barrier layer 105 may be formed by a deposition process such as a chemical vapor deposition (CVD) process, a sputtering process or an atomic layer deposition (ALD) process to include the above-described inorganic insulating material.

A conductive layer including the above-described metal may be formed on the barrier layer 105. The conductive layer may be partially removed through a photo-lithography process to form the rear metal layer BML.

Referring to FIG. 12, the buffer layer 110 covering the back metal layer BML may be formed on the barrier layer 105. The buffer layer 110 may be formed through a deposition process such as a CVD process, a sputtering process or an ALD process to include the above-described inorganic insulating material.

The first active layer ACT1 and the second active layer ACT2 may be formed on the buffer layer 110. For example, an oxide semiconductor layer may be formed on the buffer layer 110 by a sputtering process using a target including indium (In), tin (Sn), gallium (Ga) and zinc (Zn).

The oxide semiconductor layer may be patterned by the photo-lithography process to form the first active layer ACT1 and the second active layer ACT2. The first active layer ACT1 may be formed to overlap the back metal layer BML in the thickness direction.

In example embodiments, the oxide semiconductor layer may be formed at a temperature of 200° C. or less, e.g., in a range from 80° C. to 150° C., or in a range from 90° C. to 125° C.

Referring to FIG. 13, the gate insulation layer 120 may be formed on the buffer layer 110, and then the gate electrodes GE1 and GE2 and the first sub-electrode CE1 may be formed on the gate insulation layer 120.

The gate insulation layer 120 may be formed by a deposition process such as a CVD process, a sputtering process or an ALD process to include the above-described inorganic insulating material. Thereafter, a gate electrode layer may be formed on the gate insulation layer 120 by a deposition process such as a sputtering process to include the above-described metallic material.

A photoresist layer including a photosensitive resin may be formed on the gate electrode layer, and first, second and third photoresist patterns PR1, PR2 and PR3 may be formed by exposure and development processes. For example, the gate electrode layer may be partially removed by a dry etching process using the first, second and third photoresist patterns PR1, PR2 and PR3 as etching masks to form the first gate electrode GE1, the second gate electrode GE2 and the first sub-electrode CE1.

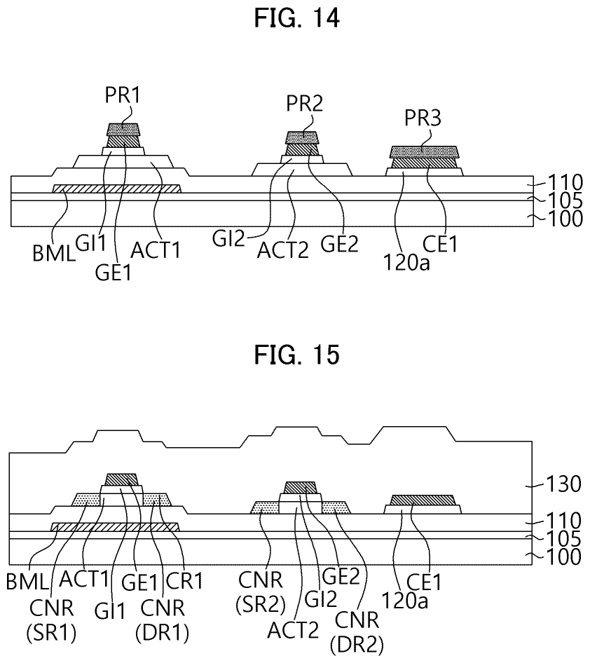

Referring to FIG. 14, the gate insulation layer 120 may be partially removed by, e.g., a dry etching process in which the photoresist patterns PR1, PR2, and PR3 are used as etching masks together with the gate electrodes GE1 and GE2 and the first sub-electrode CE1. Accordingly, the first gate insulation layer GI1, the second gate insulation layer GI2 and the sub-insulation layer 120a may be formed under the first gate electrode GE1, the second gate electrode GE2 and the first sub-electrode CE1, respectively.

As the etching process proceeds, an etching material may contact and penetrate portions of the active layers ACT1 and ACT2 exposed from the gate insulating layer 120, thereby inducing oxygen vacancies.

After the etching process, the photoresist patterns PR1, PR2, and PR3 may be removed using an ashing process and/or strip process.

Referring to FIG. 15, the insulating interlayer 130 covering the active layers ACT1 and ACT2, the gate insulation layers GI1 and GI2, the sub-insulation layer 120a, the gate electrodes GE1 and GE2, and the first sub-electrode CE1 may be formed on the buffer layer 110.

The insulating interlayer 130 may be formed by the deposition process to include the inorganic insulating material such as silicon oxide, silicon nitride or silicon oxynitride.

After the formation of the insulating interlayer 130, a heat treatment may be performed at a specific temperature. During the heat treatment, hydrogen may be transferred from the insulating interlayer 130 and/or the buffer layer 110 to the oxygen vacancies formed in exposed portions (portions not covered by the gate insulation layer) of the active layers ACT1 and ACT2.

Thus, the exposed portions of the active layer ACT1 and ACT2 may be converted into the contact region CNR having an increased conductivity. The first contact region including a first source region SR1 and a second drain region DR1 may be formed at opposite ends of the first active layer ACT1. The second contact region including the second source region SR2 and the second drain region DR2 may be formed at opposite ends of the second active layer ACT2.

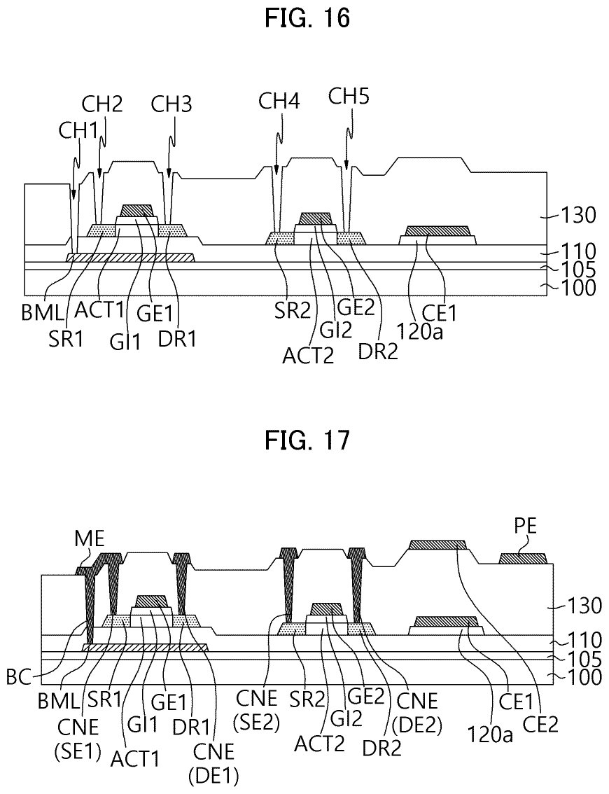

Referring to FIG. 16, the insulating interlayer 130 may be partially removed to form contact holes. For example, the insulating interlayer 130 may be partially removed by a dry etching process or a wet etching process using a photoresist pattern.

In example embodiments, a first contact hole CH1, a second contact hole CH2, a third contact hole CH3, a fourth contact hole CH4, and a fifth contact hole CH5 may be formed to expose top surfaces of the back metal layer BML, the first source region SR1, the first drain region DR1, the second source region SR2, and the second drain region DR2, respectively. The first contact hole CH1 may be formed by further etching the buffer layer 110.

Referring to FIG. 17, the connection electrode CNE filling the contact holes may be formed.

For example, a metal layer including the above-described metallic material and sufficiently filling the contact holes may be formed on a top surface of the insulating interlayer 130 by a sputtering process. The connection electrode CNE may be formed by partially etching the metal layer by a photo-lithography process. The second sub-electrode CE2 overlapping the first sub-electrode CE1 may be formed together from the metal layer.

The connection electrode CNE may include the first source electrode SE1, the first drain electrode DE1, the second source electrode SE2 and the second drain region DR2 which are in contact with or connected to the first source region SR1, the first drain region DR1, the second source region SR2 and the second drain region DR2, respectively.

The back contact BC in contact with or connected to a top surface of the back metal layer BML may also be formed from the conductive layer to be connected to the first source electrode SE1 through the merging electrode ME.

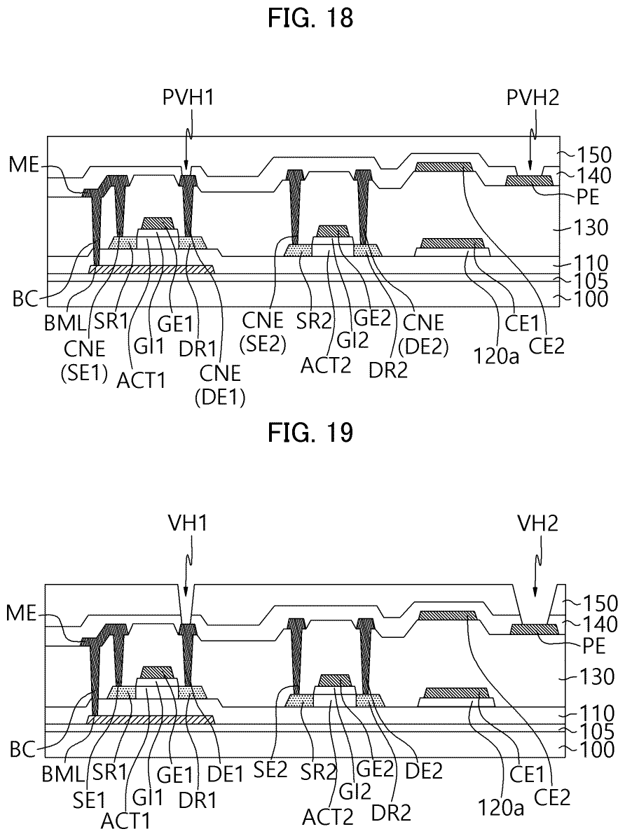

Referring to FIG. 18, the passivation layer 140 covering the connection electrode CNE, the second sub-electrode CE2 and the pad electrode PE may be formed on the insulating interlayer 130. For example, the passivation layer 140 may be formed by the above-described deposition process to include the inorganic insulating material.

The passivation layer 140 may be partially etched to form a first preliminary via hole PVH1 and a second preliminary via hole PVH2 to expose top surfaces of the first drain electrode DE1 and the pad electrode PE, respectively.

Thereafter, the planarization layer 150 may be formed on the passivation layer 140 by a coating process such as a spin coating process to include the above-described organic insulating material. The planarization layer 150 may fill the first preliminary via hole PVH1 and the second preliminary via hole PVH2.

Referring to FIG. 19, the planarization layer 150 may be partially etched to form a first via hole VH1 and a second via hole VH2 extending to the top surfaces of the first drain electrode DE1 and the pad electrode PE, respectively. The first via hole VH1 and the second via hole VH2 may be substantially merged with the first preliminary via hole PVH1 and the second preliminary via hole PVH2, respectively.

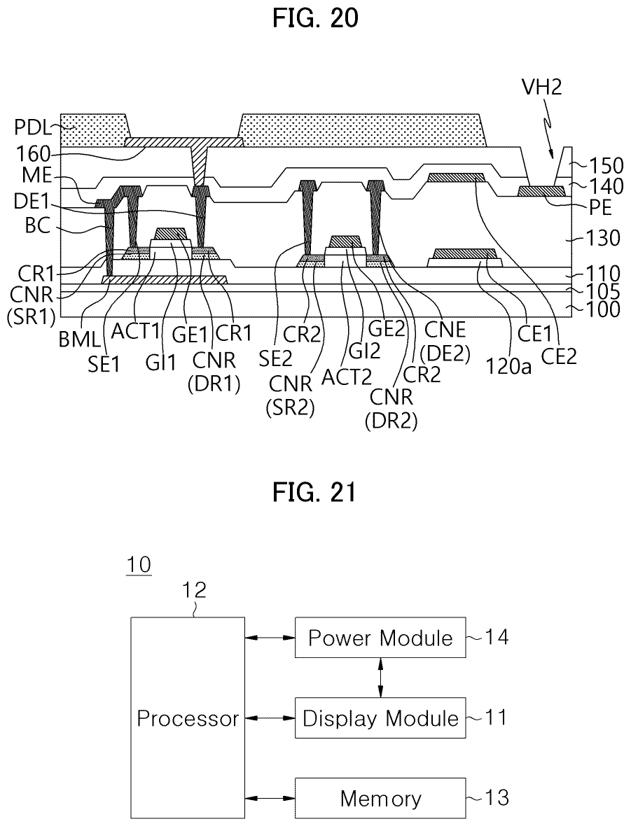

Referring to FIG. 20, the pixel electrode 160 filling the first via hole VH1 may be formed on the planarization layer 150. An electrode layer including the above-described conductive material may be formed on the planarization layer 150 to sufficiently fill the first via hole VH1. The pixel electrode 160 may be formed by partially etching the electrode layer.

Thereafter, the pixel defining layer PDL may be formed on the planarization layer 150. The pixel defining layer PDL may cover a peripheral portion of the pixel electrode 160.

In an embodiment, the pixel defining layer PDL may be formed by exposure and development processes after coating a photosensitive organic material such as a polysiloxane resin, a polyimide resin or an acrylic resin. In an embodiment, the pixel defining layer PDL may be formed by a printing process such as an inkjet printing process using a polymer material or an inorganic material.

According to embodiments of the present invention, after the formation of the above-described via holes VH1 and VH2, the pixel electrode 160, and the pixel defining layer PDL, a partial crystallization process of the active layers ACT1 and ACT2 may be performed.

In example embodiments, the partial crystallization process may include a heat treatment which is performed at a temperature of 300° C. or less, preferably less than 300° C. In the partial crystallization process, the first metal layer ML1 may act as catalyst layer donating electrons at a portion of the contact region CNR in contact with the first metal layer ML1.

Accordingly, the partial crystallization may be performed in the contact region CNR of the active layers ACT1 and ACT2 at a relatively low temperature, and thus the crystallization portion CR1 and CR2 may be formed. Thus, a portion of the contact region CNR may remain as an amorphous portion, and a substantial double-layered structure of the amorphous portion/crystallization portion may be formed in the contact region CNR.

In some embodiments, Sn and Ti may be diffused at an interface between the first metal layer ML1 and the crystallization portion CR by the partial crystallization to form the intermediate layer ITL.

In some embodiments, a temperature of the partial crystallization process may be in a range from 200° C. to 280° C., from 210° C. to 270° C., from 220° C. to 260° C., or from 230° C. to 260° C.

As described above, after the process of forming the via hole/pixel electrode 160/pixel defining layer PDL, the partial crystallization process may be performed. In some embodiments, the partial crystallization process may be performed together with a process of curing the via hole, the pixel electrode 160 and/or the pixel defining layer PDL. Thus, the partial crystallization may be implemented at a low temperature without adding a process after the formation of the contact stack structure CSS including the connection electrode CNE.

Referring back to FIG. 4, the emission layer 170 may be formed on the top surface of the pixel electrode 160 exposed by the pixel defining layer PDL and a sidewall of the pixel defining layer PDL.

The emission layer 170 may be formed by a vacuum deposition, a spin coating, an inkjet printing, a laser printing, a casting, a laser thermal transfer, or the like to include the above-described organic light-emitting material described.

As described above, the counter electrode 180 may be formed on the pixel defining layer PDL and the emission layer 170, and then the encapsulation layer 190 protecting the pixels and the counter electrode 180 may be formed. The encapsulation layer 190 may be formed of a thin film encapsulation (TFE) including a multi-layered structure of an inorganic insulating layer and an organic insulating layer.

FIG. 21 is a block diagram of an electronic device in accordance with an embodiment.

Referring to FIG. 21, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

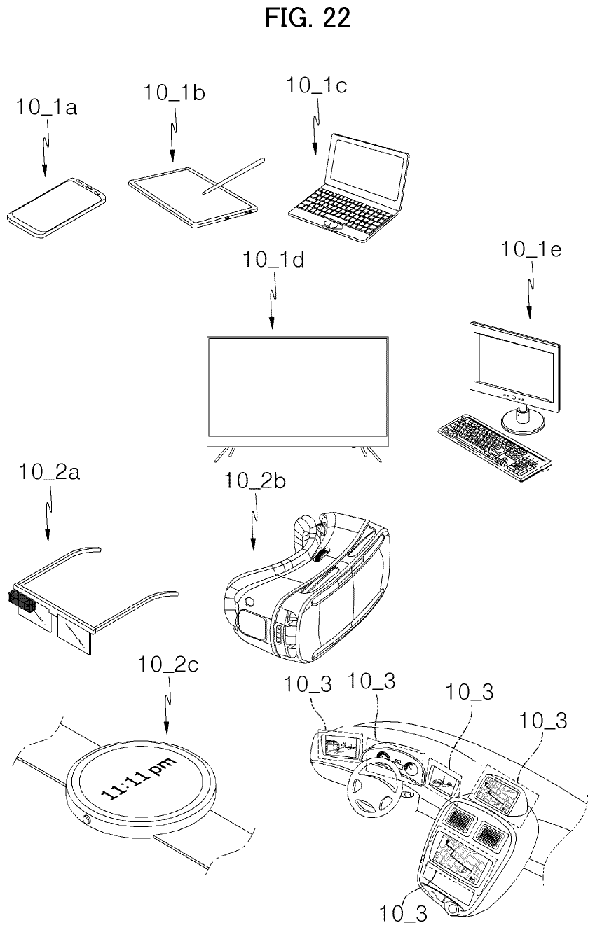

FIG. 22 is a schematic diagram of electronic devices in accordance with various embodiments.

Referring to FIG. 22, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, and the like. The electronic device may include a virtual reality glass or an augmented reality glass.

Hereinafter, an experimental example is provided to enhance understanding of the present disclosure, but the example are provided as a non-limiting example, and is not to be interpreted as limiting the scope of the attached claims. It is clear to those skilled in the art that various changes and modifications to disclosed examples can be made within the scope of the present disclosure and the technical idea.

### EXAMPLE

An active layer (a contact region) including ITGZO was formed, and a Ti layer/Al layer/Ti layer was sequentially formed on the contact region. Thereafter, a partial crystallization was induced at an interface between the Ti layer and the ITGZO layer at a temperature of 250° C. to obtain a contact stacked structure including a crystallization portion and an intermediate layer including Sn—Ti oxide.

### Comparative Example

A contact stack structure having the same thickness of each layer as that of Example was obtained except that partial crystallization was omitted.

The same voltage was applied to the contact stack structures of Example and Comparative Example to measure a contact resistance Rc multiple times, and then an average value was calculated. The average contact resistance of 457 Ω and 1107 Ω were obtained in Example and Comparative Example, respectively. The contact resistance was explicitly reduced by the partial crystallization according to the above-described embodiments.

The foregoing is illustrative of embodiments and is not to be construed as limiting the disclosure. Although a few embodiments have been described, those skilled in the art will readily appreciate that many modifications are possible in the embodiments without materially departing from the spirit of the present inventive concept. Accordingly, all such modifications and variations are intended to be included within the scope of the present inventive concept as defined in the claims.

What is claimed is:

1. A display device, comprising:
a base substrate;
an active layer including indium-tin-gallium-zinc oxide (ITGZO) on the base substrate, the active layer comprising a channel region and a contact region that is partially crystallized and formed at opposite edges of the channel region;
a gate electrode on the base substrate to overlap the channel region of the active layer;
a gate insulation layer between the active layer and the gate electrode;
a connection electrode connected to the contact region; and
a light-emitting device electrically connected to the connection electrode.

2. The display device according to claim 1, wherein the contact region of the active layer comprises an amorphous portion and a crystallization portion that is formed on the amorphous portion to be adjacent to the connection electrode.

3. The display device according to claim 2, wherein the crystallization portion has a mixed crystal structure including different crystal structures.

4. The display device according to claim 2, wherein the crystallization portion comprises indium oxide and zinc-gallium oxide.

5. The display device according to claim 2, wherein the crystallization portion overlaps an entire width of a bottom surface of the connection electrode.

6. The display device according to claim 5, wherein an edge of the bottom surface of the connection electrode is separated from an outermost perimeter of a top surface of the crystallization portion by a predetermined distance in a horizontal direction.

7. The display device according to claim 5, wherein the bottom surface of the connection electrode has a shape inserted into the crystallization portion, and
a boundary between the connection electrode and a top surface of the crystallization portion is separated from an outermost perimeter of the top surface of the crystallization portion by a predetermined distance in a horizontal direction.

8. The display device according to claim 2, wherein the crystallization portion includes a plurality of transition sections in which a thickness of the crystallization portion increases or decreases along a horizontal direction.

9. The display device according to claim 8, wherein the crystallization portion has a maximum thickness in a region corresponding to a point between one edge of the bottom surface of the connection electrode and a center of the bottom surface of the connection electrode.

10. The display device according to claim 9, wherein a thickness of the crystallization portion in a region corresponding to the one edge of the bottom surface of the connection electrode is greater than a thickness of the crystallization portion in a region corresponding to the center of the bottom surface of the connection electrode.

11. The display device according to claim 2, wherein the connection electrode comprises a first metal layer including titanium (Ti) adjacent to the crystallization portion in the contact region.

12. The display device according to claim 11, further comprising an intermediate layer between the crystallization portion and the first metal layer,
wherein the intermediate layer includes an oxide containing tin (Sn) and Ti.

13. An electronic device, comprising:
the display device of claim 1;
a memory; and
a processor configured to execute data included in the memory to control an operation of the display device.

14. A display device, comprising:
a base substrate;
an active layer including indium-tin-gallium-zinc oxide (ITGZO) on the base substrate, the active layer comprising a channel region and a contact region formed at opposite edges of the channel region;
a gate electrode on the base substrate to overlap the channel region of the active layer;
a gate insulation layer between the active layer and the gate electrode;
a connection electrode connected to the contact region;
an intermediate layer between the connection electrode and the contact region, the intermediate layer including an oxide containing tin (Sn) and Ti; and
a light-emitting device electrically connected to the connection electrode.

15. The display device according to claim 14, wherein the contact region of the active layer comprises an amorphous portion and a crystallization portion, and
the intermediate layer is formed between a bottom surface of the connection electrode and the crystallization portion.

16. The display device according to claim 15, wherein the crystallization portion has a mixed crystal structure of a cubic crystal structure and a spinel crystal structure.

17. The display device according to claim 15, wherein the connection electrode comprises a first metal layer including titanium (Ti), a second metal layer including aluminum (Al) and a third metal layer including titanium (Ti) which are sequentially stacked from the crystallization portion.

18. A method of manufacturing a display device, comprising:
forming an active layer comprising indium-tin-gallium-zinc oxide (ITGZO) on a base substrate;
forming a gate insulation layer covering the active layer;
forming a gate electrode on the gate insulation layer;
forming a contact region by increasing a conductivity of opposite edges of the active layer;
forming a connection electrode connected to the contact region;
forming a planarization layer covering the active layer, the gate insulation layer, the gate electrode and the connection electrode;
forming a via hole by partially removing the planarization layer to expose a top surface of the connection electrode;
forming a pixel electrode filling the via hole and being connected to the connection electrode; and
partially crystallizing the contact region of the active layer after forming the via hole or after forming the pixel electrode.

19. The method of claim 18, wherein the partially crystallizing is performed at a temperature of 300° C. or less.

20. The method of claim 18, wherein the partially crystallizing comprises forming a crystallization portion at an upper portion of the contact region and an intermediate layer containing tin (Sn) between the crystallization portion and a bottom surface of the connection electrode.
